(19) United States
(12) Patent Application Publication
(10) Pub. No.: US 2007/0040202 A1
(43) Pub. Date: Feb. 22, 2007

(54) Semiconductor memory cell array having self-aligned recessed gate MOS transistors and method for forming the same

(75) Inventors: Gerhard Enders, Olching (DE); Marc Strasser, Munchen (DE); Peter Voigt, Hallbergmoos (DE); Bjorn Fischer, Munchen (DE)

Correspondence Address: MORRISON & FOERSTER LLP, 1650 TYSONS BOULEVARD, SUITE 300, MCLEAN, VA, 22102, US

(73) Assignee: INFINEON TECHNOLOGIES AG, Munich (DE)

(21) Appl. No.: 11/206,306

(22) Filed: Aug. 18, 2005

(51) Int. Cl. H01L 29/94; H01L 21/8242

(52) U.S. Cl. 257/301; 257/296; 438/243; 438/386

(57) ABSTRACT

In a semiconductor memory including an array of memory cells, each memory cell includes a trench capacitor, the trench capacitor including an inner electrode, an outer electrode and a dielectric layer disposed between the inner electrode and the outer electrode, and a selection transistor, the selection transistor including a first source/drain area, a second source/drain area and a channel region disposed between the first source/drain area and the second source/drain area in a recess, the trench capacitor and the selection transistor of each memory cell are disposed side by side, the first source/drain area of the selection transistor being electrically connected to the inner electrode of the trench capacitor, the recess in which the channel region of the selection transistor is formed being located self aligned between the trench capacitor of the memory cell and the trench capacitor of an adjacent memory cell.

### TECHNICAL FIELD OF THE INVENTION

The invention relates to a semiconductor memory including an array of memory cells and a method for forming the same, and more particularly to a semiconductor memory including an array of memory cells, each memory cell comprising a trench capacitor and a selection transistor having a recessed gate electrode and a method for forming the same.

### BACKGROUND OF THE INVENTION

In dynamic random access memories (DRAMs), use is predominantly made of one-transistor memory cells which are composed of a selection transistor and a storage capacitor, wherein the information is stored in the storage capacitor in the form of electrical charges. A DRAM comprises an array of memory cells which are connected in the form of rows and columns. Usually, the rows are designated as word lines and the column lines are designated as bit lines. The selection transistor and the storage transistor of the memory cells are connected to one another in such a way that when the selection transistor is driven via a word line, the charge of the storage capacitor can be read in and out via a bit line.

One focus in the technological development of DRAMs is the storage capacitor. In order to provide an adequate storage capacitance in the context of continually scaled-down memory cell array three dimensional storage capacitors have been developed. Such three-dimensional storage capacitors are often embodied as trench capacitors in DRAM memory cells. In the case of such trench capacitors a trench is etched into the semiconductor substrate and is filled with a dielectric layer and a first inner storage electrode. An adjacent region of the semiconductor substrate serves as a second outer storage electrode.

The selection transistor of a DRAM memory cell is preferably formed as a field-effect transistor on the planar semiconductor surface aside from the trench capacitor. The selection transistor has a first source/drain electrode and a second source/drain electrode with an active region in between. Arranged above the active region are a gate-insulation layer and a gate electrode which act as a plate capacitor by which the charge density in the active region can be influenced in order to form or to block a current conductive channel between the first source/drain electrode and the second source/drain electrode. One of the source/drain electrodes of the selection transistor is connected to the inner storage electrode of the trench capacitor.

In addition to the trench capacitors the selection transistors are also the subject of technological development. The performance of small field-effect transistors used as selection transistors can be affected by short-channel effects. To reduce a junction leakage current, field-effect transistors which have a gate electrode formed in a recess resulting in a small critical dimension and a long channel have been developed.

DRAM wafers primary made of silicon wafers are produced with the aid of silicon planar technology. The structuring of the silicon wafer in order to form the individual DRAM components is carried out by means of lithographic technology. The desired component structures are first of all generated via a photomask in a thin radiation-sensitive film and are transferred into the layer lying underneath the photomask with the aid of specific etching processes.

As the feature size of the DRAM cells are becoming increasingly small high demands are imposed on the geometric conditions of the cell structure and on the technological procedure, in particular on the overlay tolerances of lithography processes and on the electrical performance of the selection transistor. The spacing between critical cell structures which are located on different lithography levels must be selected in such a way that the maximally possible deviation from an exact overlay of the cell structures does not impair the function of the memory components.

Within the DRAM-cell concept the spacing between the trench capacitor and the gate electrode of the selection transistor is one of the most critical distances. A reduction of feature size means that the interface between the inner storage electrode of the trench capacitor is moving ever closer to the channel region of the selection transistor. A lithographical overlay deviation of the gate electrode level with respect to the trench capacitor level, however, prevents such a further minimization of the spacing between the trench capacitor and the gate electrode of the selection transistor. This disadvantage particularly applies if the selection transistor is carried out as a field-effect transistor with a recessed gate electrode. Prior art solutions to solve this problem consist of an introduction of new lithographic tools. However, improved lithography installations to reduce the overlay tolerance of the gate electron level of selection transistor with respect to the trench capacitor level are not able to guarantee a sufficient accuracy of level overlay starting from the 65 nm technology generation.

### SUMMARY OF THE INVENTION

In one embodiment of the invention, there is a semiconductor memory and a method for forming such a semiconductor memory which overcomes the above-mentioned disadvantages of hereto known devices and methods. According to the invention a semiconductor memory and a method for forming such a semiconductor memory are provided having an improved overlay accuracy of the gate electrode level of a selection transistor having a recess electrode with respect to the trench capacitor level.

In accordance with the invention, a semiconductor memory including an array of memory cells and a method for forming such a semiconductor memory, each memory cell comprises a trench capacitor, the trench capacitor including an inner electrode, an outer electrode and a dielectric layer disposed between the inner electrode and the outer electrode and a selection transistor, the selection transistor comprising a first source/drain area, a second source/drain area and a channel region disposed between the first source/drain area and the second source/drain area in a recess, the trench capacitor and the selection transistor of each memory cell being disposed side by side, the first source/drain area of a selection transistor being electrically connected to the inner electrode of a trench capacitor, the recess in which the channel region of a selection transistor is formed being located self-aligned between the trench capacitor of the memory cell and the trench capacitor of an adjacent memory cell.

According to the invention, the recessed gate electrode of the selection transistor is produced self-aligned with respect to the trench capacitor. Consequently, no overlay deviation between the trench capacitor level and the selection transistor level having a recessed gate electrode occurs. According to the invention, no adjusting steps for positioning the selection transistor having a recessed gate electrode with respect to the trench capacitor is needed. Therefore, the spacing between the recessed gate electrode of the selection transistor and the trench capacitor can be reduced. The reduced area requirement by putting the recessed gate electrode of the selection transistor closer to the trench capacitor can be either used to make the memory cell smaller or to enlarge the diameter of the trench capacitor resulting in an increased capacitor capacitance and thus an improved cell performance. Alternatively, the earning of space by reducing the spacing between the recessed gate electrode of the selection transistor and the trench capacitor can be used to increase the contact area between a source/drain electrode of the selection transistor and a bit line which leads to a lower contact resistance and thus to a larger process window for the overlay step of the bit line level with respect to the source/drain area level of the selection transistor.

In accordance with another embodiment of the invention, the spacing between the gate recess of the selection transistor and the trench capacitor of the memory cell approximately corresponds to the spacing between the gate recess of the selection transistor and the trench capacitor of an adjacent memory cell.

In accordance with still another embodiment of the invention, the memory cells are arranged in rows and columns, wherein the trench capacitor and the selection transistor of each memory cell are arranged along the bit lines allocated to the rows and arranged orthogonal to the word lines allocated to the column.

In accordance with yet another embodiment of the invention, one of the source/drain areas of the selection transistor is electrically connected via a buried strap area to the inner storage electrode of the trench capacitor.

In accordance with one embodiment of the invention, forming an array of trench capacitors includes etching an array of trenches into the semiconductor substrate, doping the semiconductor substrate around the lower part of said trenches to form the outer electrodes, disposing a dielectric layer on the wall of the trenches, filling the trenches with a first conductive material to form the inner storage electrodes, etching the first inner storage electrode filling back to a first depth of the trenches, coating the exposed wall of the trenches above the inner electrode with a first insulation layer, filling the trenches with a second conductive material to form an electrical connection to the inner storage electrode, etching the second conductive material back to a second depth of the trench being lesser than the first depth, removing the first insulation layer coating from the wall of the trenches, filling the trenches with a third conductive material, etching the third conductive material in a manner to form a buried strap at a wall region of the trenches, filling the trenches with a second insulation material, and forming a step between a second insulation material and the adjacent region in such a way that the second insulation material protrudes, and wherein the step of forming an array selection transistors includes the steps of selectively growing on the second insulation material as spacer, the thickness of said spacer approximately corresponding to the spacing between the channel region of the selection transistor and the trench, etching an array of recesses into the semiconductor substrate using the spacer as a mask, disposing a gate insulation layer on the walls of the recesses,

filling the recesses with a fourth conductive material to form the gate electrodes, etching the fourth conductive material back to a third depth of the recesses, coating the exposed wall of the recesses above the fourth conductive material with a third insulation layer, filling recesses with a second conductive material to form an electrical connection to the gate electrodes, etching the spacer, and doping the semiconductor substrate on both sides of the recesses down to the third depth of the recesses to form the first source/drain area and the-second source/drain area, the first source/drain area adjoining said buried strap at the wall region of the trenches.

In accordance with another embodiment of the invention, a pad layer is formed on the regions being adjacent to the second insulation material filling the trenches, wherein the step between the second insulation material and the adjacent regions is formed by etching the pad layer anisotropic and selectively to the second insulation material.

In accordance with still another embodiment of the invention, the second insulation material on top of the trenches is a multi-layer system having a poly-silicon layer on the top wherein the spacer selectively grown on the second insulation material is a poly-silicon spacer.

In accordance with yet another embodiment of the invention, the poly-silicon spacer is oxidized after deposition.

In accordance with another embodiment of the invention, the pad multilayer system serves as an etching mask for etching the trenches, said multilayer system including as a base layer an oxide layer.

In accordance with still another of the invention, the doping of the third conductive material forming the buried strap at a wall region of the trenches is selected in such way that taking into account the temperature budget of the succeeding processes a sufficient quantity of dopant out-diffuses in order to ensure a sufficiently low resistive connection of the inner storage electrode of the trench capacitors to the second source/drain area of the selection transistor.

In accordance with a further embodiment of the invention, the etching of the third conductive material in a manner to form the buried strap at the wall region of the trenches includes the step of locally changing the etching rate of a sacrificial layer on top of the third conductive material by a tilted implantation, and the step of removing the region of the third conductive material beneath the sacrificial layer showing the tilted implantation.

In accordance with a further embodiment of the invention, the filling of the trenches with a second insulation material includes the step of growing a thin silicon dioxide layer, the step of filling the trenches with a CVD oxide and the step of back-polishing the CVD oxide.

In accordance with a further embodiment of the invention, after the filling of the trench with a second insulation material, shallow trench isolations between adjacent memory cells are carried out.

One advantage of the invention is that, as a result of the self-adjusting arrangement of the recessed gate electrode of the selection transistor in relation to the trench capacitor, the spacing between the recessed gate electrode of the selection transistor and the trench capacitor is fixed without any overlay deviation. Therefore, the nominal distance between the recessed gate electrode of the selection transistor and the trench capacitor can be reduced. The self-adjustment process of positioning the recessed gate electrode of the selection transistor with respect to the trench capacitor enables an abandonment of a critical lithographic mask and of the corresponding lithographic process steps regularly used to overlay the recessed gate electrode level of the selection transistor with the trench capacitor level. The self-adjustment of the recessed gate electrode of the selection transistor in relation to the trench capacitor is achieved in that the etching mask used to structure the recessed gate electrode is formed by an enlargement of the trench capacitor structure wherein the spacing between the recessed gate electrode and the trench capacitor is defined by the thickness of a deposited layer. The variation of the deposited layer thickness can be kept far smaller than the overlay tolerance of two lithographic levels which have to be adjusted with respect to each other.

### BRIEF DESCRIPTION OF THE DRAWINGS

The invention is described below in more detail with reference to exemplary embodiments illustrated in the drawings, in which:

FIG. 1 shows a circuit diagram of a dynamic memory cell in a DRAM.

FIG. 2 shows a plane-view layout of the invention having a memory cell arrangement in the form of a checkerboard pattern.

FIGS. 3 to 18 are partial vertical sections illustrating stages 1 to 16 in a fabrication method according to the invention.

### DETAILED DESCRIPTION OF THE INVENTION

The invention is explained using a process for forming a silicon-based DRAM. The individual structures of a dynamic memory cell are preferably formed with the aid of the silicon planar technology which comprises a sequence of individual processes acting in each case in a whole-area manner on the surface of a silicon substrate, wherein local changes of the silicon substrate are carried out by means of suitable masking layers. During the DRAM-memory-fabrication, a multiplicity of memory cells are simultaneously formed.

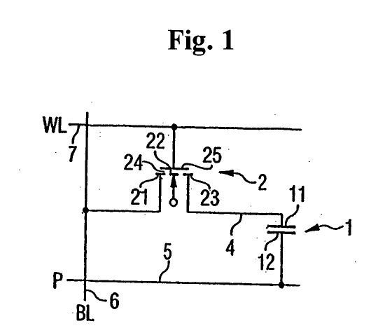

In DRAMs, use is predominantly made of a one-transistor memory cell whose circuit diagram is shown in FIG. 1. A one-transistor memory cell comprises a storage capacitor 1 and a selection transistor 2. The selection transistor 2 is preferably formed as a field-effect transistor having a first source/drain electrode 21 and a second source/drain electrode 23 between which an active region 22 is arranged. Above the active region 22 a gate-insulation layer 24 and a gate electrode 25 are located which act like a plate capacitor by which a charge density in the active region 22 can be influenced in order to form or to block a current conduction channel between the first source/drain electrode 21 and the second source/drain electrode 23.

The second source/drain electrode 23 of the selection transistor 2 is connected to a first storage electrode 11 of the storage capacitor 1 via a connecting line 4. The second storage electrode 12 of the storage capacitor 1 is in turn connected to a capacitor plate 5 which is preferably common to the storage capacitors of the DRAM cell arrangement. The first source/drain electrode 21 of the selection transistor 2 is further connected to a bit line 6 so that information stored in the storage capacitor 1 in the form of charges can be read in and out. This read in and read out operation is controlled via a word line 7 which is preferable simultaneously the gate electrode 25 of the selection transistor in order to produce a current conductive channel in the active region 22 between the first source/drain electrode 21 and the second source/drain electrode 23 by application of a voltage.

In DRAM cells, an area reduction of the cell array can be achieved by the virtue of three-dimensional structures. Therefore the storage capacitor is preferably formed as a trench capacitor having a trench which is etched into the silicon substrate and typically is embodied with a highly doped silicon used as an inner storage electrode. This poly-silicon filling is insulated in the lower trench region by a storage dielectric layer from an outer storage electrode which is formed by introducing a dopant into a lower trench region. In the upper trench region the poly-silicon filling is isolated from the silicon substrate by an insulation layer in order to prevent a parasitic transistor from arising along the trench.

The selection transistor which is embodied in a planar manner at the silicon substrate surface has two diffusion regions which form the two source/drain electrodes, one diffusion region adjoining the trench. A capacitor connection a so-called buried strap contact is embodied in this region and connected to the diffusion region of the selection transistor to the poly-silicon filling in the trench capacitor. To improve the performance of the selection transistor, particularly to reduce short channel effects, the gate electrode of the selection transistor is formed in a recess resulting in a small critical dimension and a long active region.

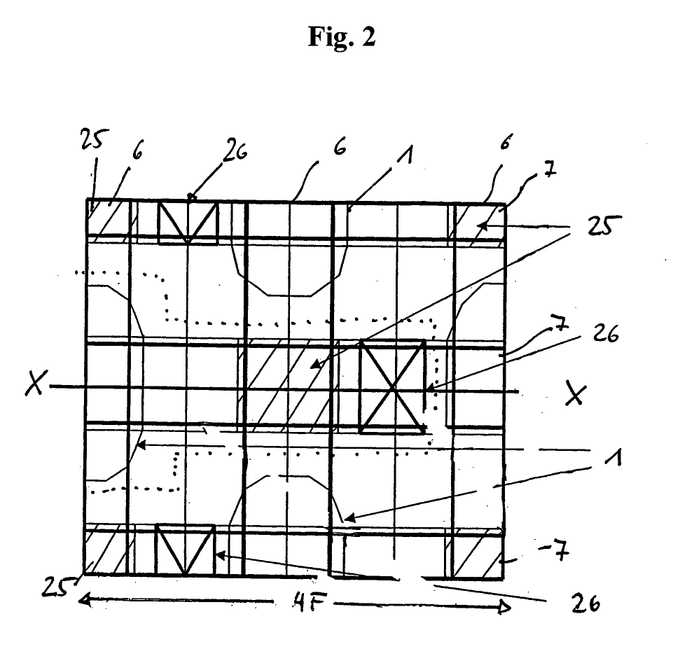

FIG. 2 shows a preferred semiconductor memory layout. The DRAM cell array is preferably arranged in a checkerboard geometry, the memory cells being lined up along the bit lines 6 running in vertical rows, the bit lines crossing word lines 7 running in horizontal rows. Arranged below the vertical running rows of the bit lines are the selection transistors 2, the first source/drain electrode 21 of the selection transistors being contacted with them by the bit line contact 26. The bit line contacts 26 of the individual rows are arranged offset from one another as shown by the plane view of FIG. 2 in order to form the checkerboard geometry. The recessed gate electrodes 25 are arranged below the intersection points of the bit lines 6 and the word lines 7 and likewise produce the checkerboard geometry. In FIG. 2 a DRAM cell is delimited by a dotted line. By using the checkerboard geometry to arrange the memory cell array, the distance between adjacent memory cells can be reduced to 4F wherein F represents the minimum structure dimension achievable with the applied lithographic technique.

The memory cell size for DRAMs having a structure size of 100 nm and below is substantially limited by the achievable lithographic overlay tolerances. The spacing between the structure elements which are located on different lithographic levels must be selected in such a way that the maximum possible deviation does not affect the function of the component. The most critical structure size of the DRAM memory cells is the distance between the trench capacitor and the active region of the selection transistor. This particularly applies to selection transistors having a recessed gate electrode.

The inventive concept solves the adjustment problem by positioning the recessed gate electrode of the selection transistor self-adjusted with respect to the position of the trench capacitor. In consequence, no adjustment tolerance has to be considered when positioning the recessed gate electrode of the selection transistor in relation to the trench capacitor. Thus, the spacing between the recessed gate electrode of the selection transistor and the trench capacitor can be carried out minimally. The reduction of the spacing between the recessed gate electrode of the selection transistor and the trench capacitor can be used either to make the memory cell smaller or to increase other critical structure dimensions. It may be possible to enlarge the trench diameter which leads to an increased cell capacitance and thus to an improved cell performance. Alternatively or additionally, the bit line contact area may be increased to lower the contact resistance. By positioning the recessed gate electrode of the selection transistor self-adjusted with respect to the position of the trench capacitor, critical lithographic process can be avoided.

In order to carry out the recessed gate electrode of the selection transistor self-adjusted with respect to the trench capacitor, the etching mask to structure the recessed gate electrode is formed by enlarging the trench structure. By forming a layer with a predetermined thickness on a projecting isolation cap on top of the trench capacitor, the spacing between the trench capacitor and the recessed gate electrode of the selection transistor is determined. This control of the layer thickness defining the position of the gate recess is far easier than the adjustment of two lithographic levels as done in the prior art.

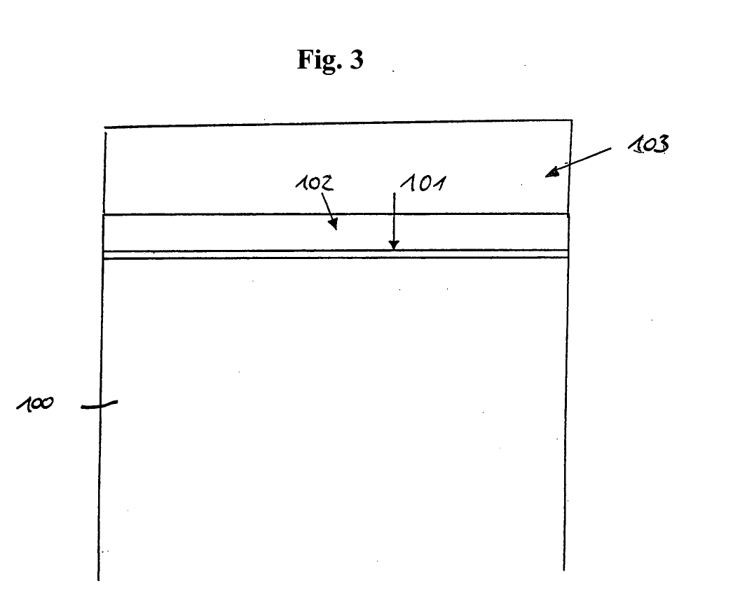

FIGS. 3 to 18 show a possible process sequence for forming a DRAM according to the invention having a memory cell array, each cell comprising a trench capacitor and a selection transistor having a recessed gate electrode, said recessed gate electrode being positioned self-adjusted with respect to the trench capacitor. Each of FIGS. 3 to 18 presents a cross-section along the XX-line of FIG. 2 illustrating the silicon wafer after the last individual process described. In the following description, the process steps for forming the dynamic memory cells which are essential to the invention are discussed. The process sequence described must be extended by the process steps which are necessary to produce the support components of the DRAM.

In a first process sequence, the trench capacitor is formed. A p-doped silicon wafer 100 is the starting point. The silicon wafer 100 is etched to form the trench holes in a first step. As illustrated in FIG. 3, an etching mask is applied to the silicon substrate for this purpose. The multi-layer etching mask includes a thermal oxide layer 101, a nitride layer 102 and a further oxide layer 103 preferably made from boron silicate glass deposited by means of chemical vapor deposition (CVD). Instead of a thermal oxide layer a oxynitride layer may be used. The thickness of the basic thermal oxide layer 101 is selected so that the thermal oxide layer is thick enough to guarantee the isolation of a word line with respect to the silicon substrate if a misalignment between a recessed gate electrode and the word line occurs. The thermal oxide layer 101 is approximately 5 nm thick, the nitride layer 102 has a thickness of preferably 200 nm. The thickness of the oxide layer is preferably approximately 1000 nm.

A photoresist layer is applied to the multilayer etching mask, said photoresist layer being exposed a lithographic process and subsequently etched to define the trench holes. Thereafter, the multilayer etching mask is structured by an anisotropic etch using the structured photoresist layer and then the silicon substrate is etched down to a predetermined depth in order to produce the trench holes 107. The etching of the silicon substrate may be carried out in a two-state etching process to form a bottled trench hole having an increased trench capacitance.

After the etching of the trench holes 104, both the photoresist layer and the top oxide layer 103 of the multi layer etching mask are removed. Then, the outer storage electrode 105 of the trench capacitor is formed as a buried plate. For this purpose, an arsenic-doped oxide layer is deposited in each trench hole 104. The arsenic-doped oxide layer is etched back down to a first depth, preferably down to the bottle-neck of the trench hole. A further oxide layer is applied on the arsenic-doped oxide layer by means of CVD. Then an out-diffusion process follows to produce an n-doped region 105 in the silicon substrate 100, around the lower wider part of the trench. The n-doped area is denoted as the buried plate and serves as an outer storage electrode of the trench capacitor.

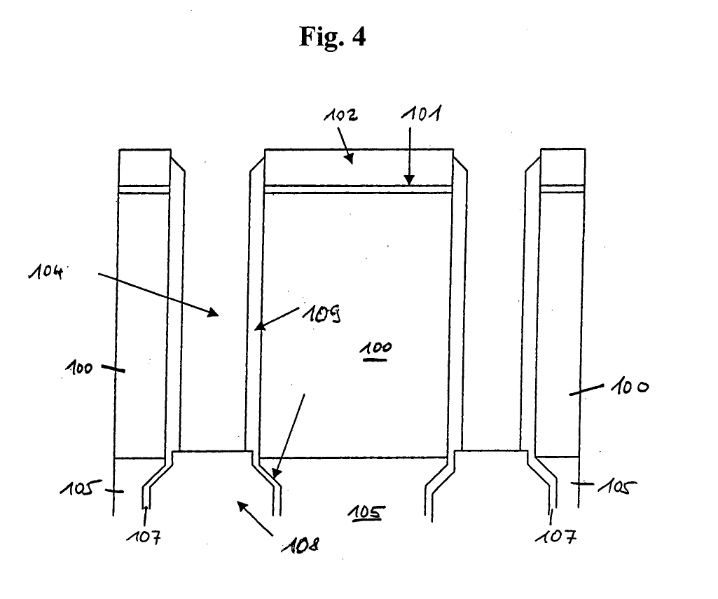

After the removal of the oxide layer and the arsenic-doped layer out of the trench holes, a dielectric layer 107 is applied to the inner side of the trench holes. The dielectric layer 107, preferably an ONO-layer, an NO-layer or an NONO-layer, serves as a dielectric of the trench capacitor. Then the lower wider region of the trench holes is filled with a first n-doped poly-silicon layer 108. For this purpose, the entire trench hole is filled with n-doped poly-silicon 108 and then the n-doped poly-silicon is etched back down to the first depth corresponding to the bottle-neck of the trench holes in a first recess step. Subsequently, the dielectric layer 107 beyond the poly-silicon filling is removed from a sidewalls of the trench holes 104. Next, a so-called collar oxide layer 108 is deposited on the side walls of the trench holes by means of CVD in the region above the dielectric layer 107. The collar oxide layer 18 is preferably composed of silicon dioxide and serves to prevent parasitic current between the outer storage electrode and the selection transistor of the memory cell described further below. The state of the method after forming the collar oxide is shown in FIG. 4, wherein FIG. 4 presents a cross-section with two adjacent trench holes.

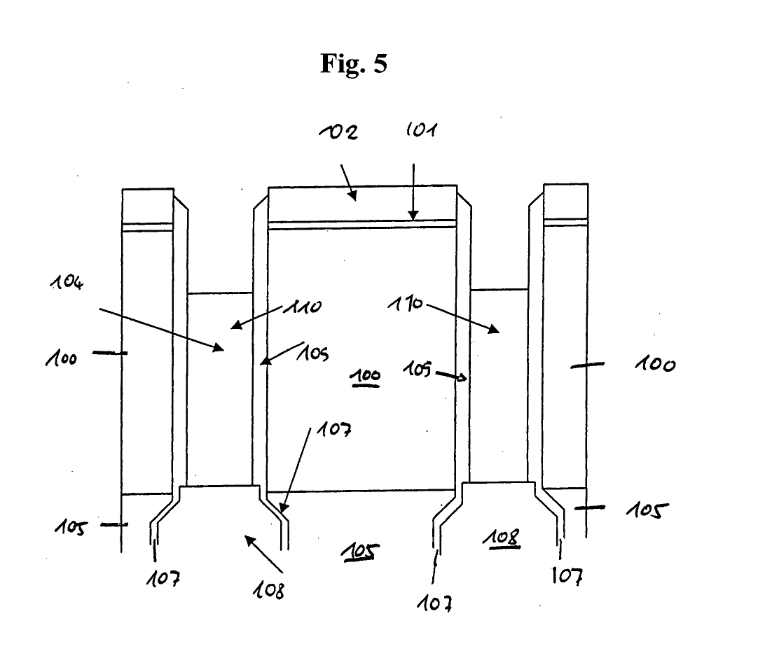

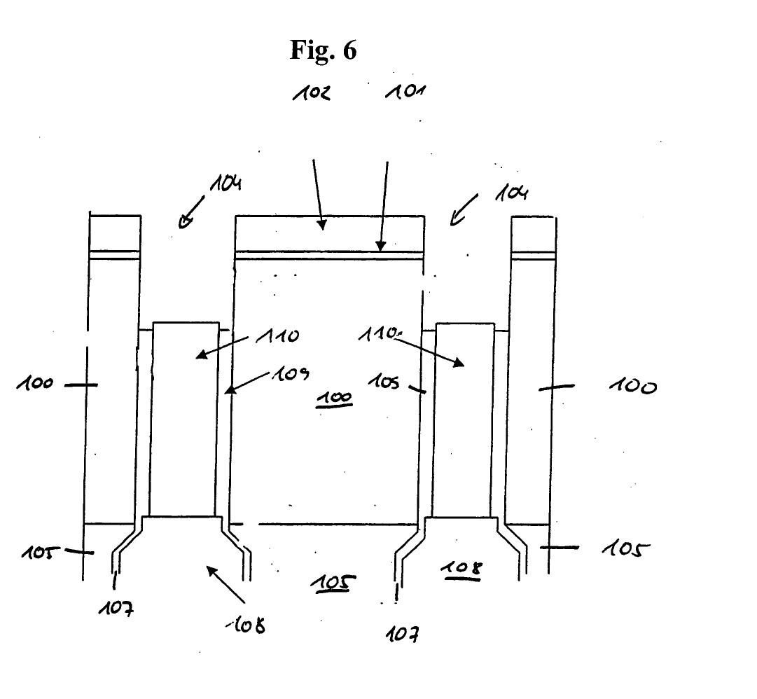

Next, a second n-doped poly-silicon layer 110 is deposited in the trench holes 104 and subsequently etched back down to a second depth below the silicon substrate surface in a second recess step. This method state is shown in FIG. 5. Next, the collar oxide 109 is removed until below the upper edge of the n-doped second poly-silicon layer 110. This step of the method is shown in FIG. 6.

Another n-doped poly-silicon layer 111 is deposited in the trench holes 104 doped in a further method step. The third n-doped poly-silicon layer 111 is etched down to a third depth, preferably 30 nm under the silicon substrate surface in a third recess step following thereupon. The doping rate of the third n-doped poly-silicon layer 111 is selected in such a way that the temperature budget of the total memory cell forming process is of sufficient quantity to out-diffuse the dopant by the buried strap window described further below in order to ensure a sufficiently low resistance connection to a source/drain area of a selection transistor.

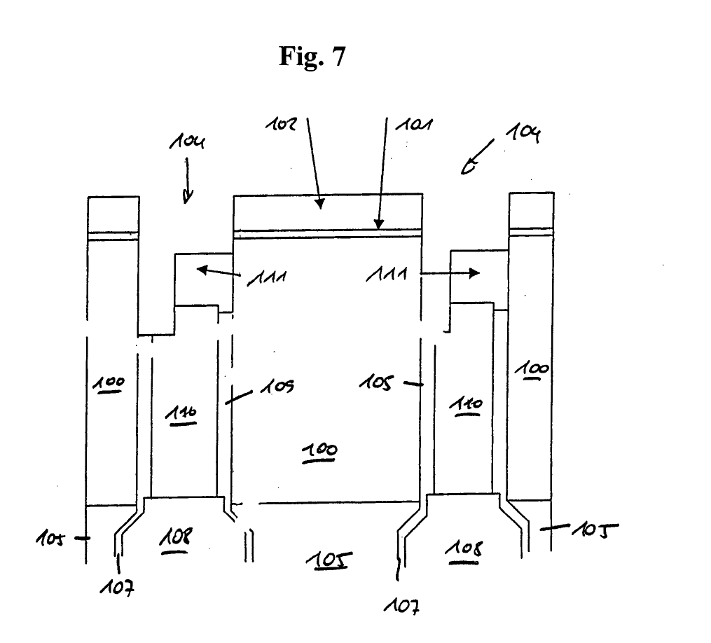

In the following process sequence, a buried strap window is defined. On the side opposite to the position of the selection transistor, the third n-doped poly-silicon layer 111 is removed. This removal is carried out by a tilted implantation of ions into a sacrificial layer on top of the third poly-silicon layer 111 changing the etching rate of the sacrificial layer locally in this area so that the sacrificial layer and the poly-silicon layer 111 can be removed by the etching only in the desired region. In a further etching step, the recess in the third n-doped poly-silicon layer 111 is deepened into the second n-doped poly-silicon layer 110. This state of the method is shown in FIG. 7.

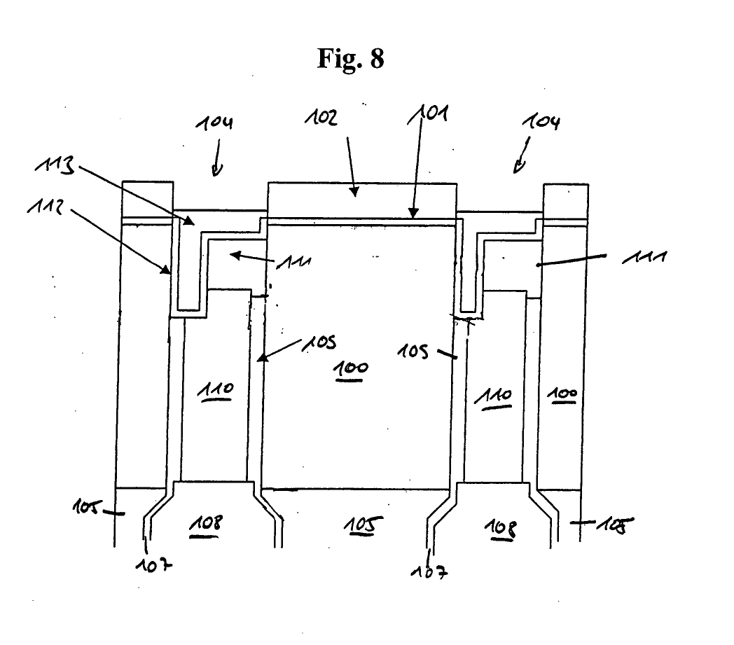

In a next process step, an isolation cap is carried out on top of the trench holes 104. First, a thin first oxide layer 112 is preferably thermally grown, the first oxide layer having a thickness of about 5 nm. The first oxide layer 112 is formed to improve the interface to the poly-silicon layers. Then, the trench hole 104 is filled with a second oxide layer 113 by means of CVD, said second oxide layer 113 being polished down to the upper edge of the nitride layer 102 and then etched back approximately 50 nm underneath the upper edge of the nitride layer 102. This state of the method is shown in FIG. 8.

In a next process sequence, the position of a recess in which a gate electrode of a selection transistor is formed is defined in a self-adjusted manner. The basic principle to arrange the position of the recessed gate electrode of the selection transistor self-adjusted with respect to the position of the trench capacitor includes the fact that the mask used for structuring the gate recess is carried out by enlarging the trench hole structure. For this, a layer with a defined thickness is deposited on the trench cap projecting from the surface adjacent to the trench. Since the variation of a layer thickness can be controlled precisely, no variation in the distance between the recess to form the gate electrode of the selection transistor and the trench hole occurs. According to the inventive concept, the spacing between the recess in which the gate electrode of the selection transistor is formed and the trench capacitor is defined without the need of an adjustment of two lithographic levels.

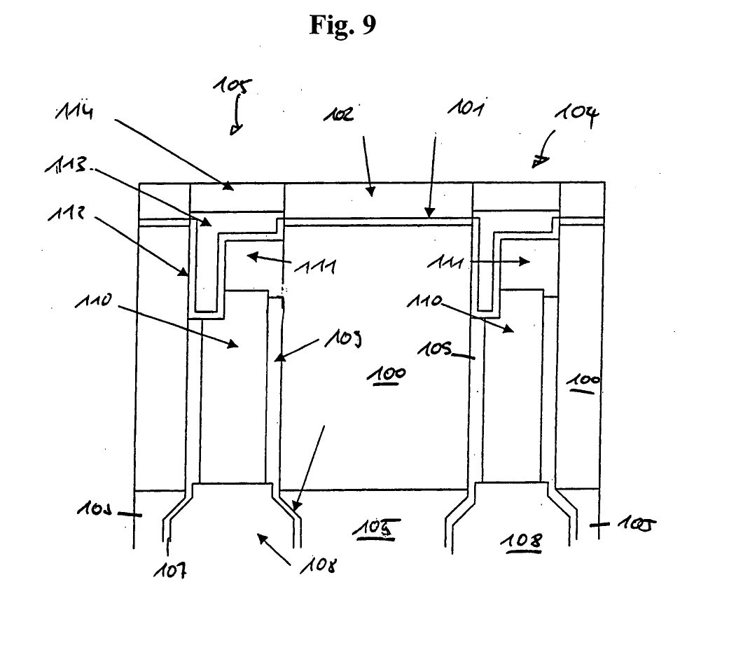

Starting from the state of the method shown in FIG. 8, a poly-silicon layer 114 is deposited in the recess on top of the oxide cap layer 113. Then the poly-silicon layer 114 is polished back to the upper edge of the adjacent nitride layer 102. This state of the method is shown in FIG. 9.

Before defining the position of the recess to form the gate electrode of the selection transistor, an intermediate process to form shallow trench isolations between the memory cells is carried out. The shallow trenches are etched into the silicon substrate. Then, the shallow trenches are filled with an oxide layer preferably using the HDP process. The oxide layer filling the shallow trenches is polished back to the upper edge of the nitride layer 102.

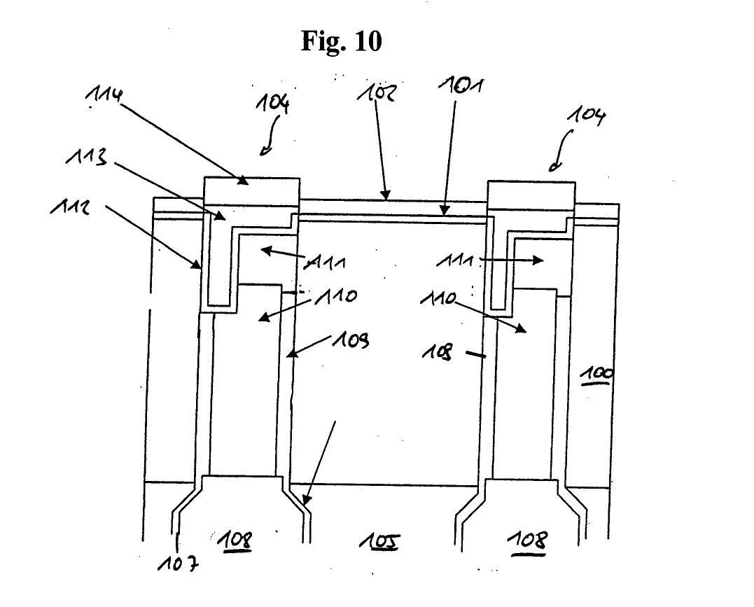

After the formation of the shallow trench isolations, a step between the poly-silicon layer 114 on top of the trench 104 and the nitride layer 102 is formed by etching the nitride layer 102 anisotropically and selectively to the shallow trench isolations and the poly-silicon layer 102. This state of the method is shown in FIG. 10.

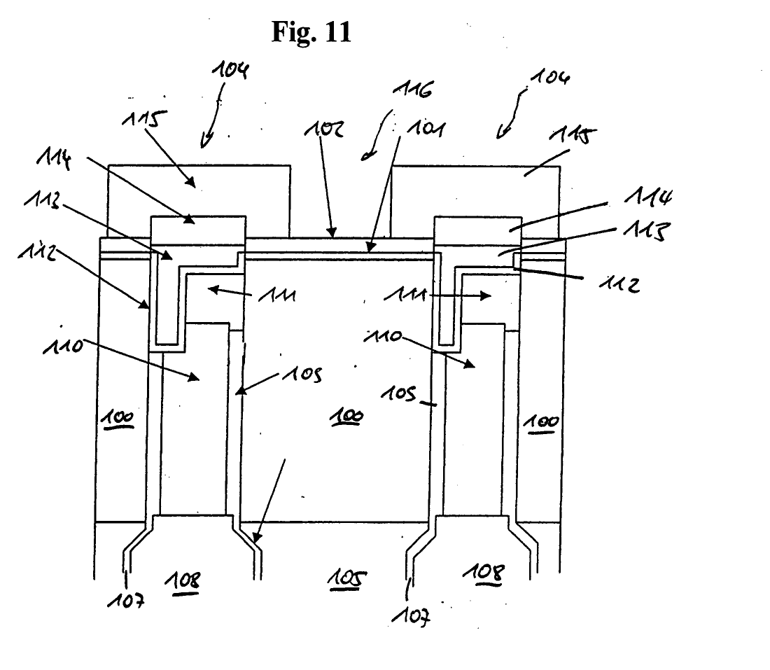

Then, a poly-silicon mask layer 115 is selectively grown on the poly-silicon cap layer 114 covering the trenches 104. The opening 116 between two adjacent poly-silicon mask layers 115 grown on top of the trenches 104 define the position and the diameter for the recess in which the gate electrode of the selection transistor is formed. The adjustment of the recess position is carried out via controlling of the thickness of the poly-silicon mask layers 115 grown on top of the trenches 104. A cross-section after the formation of the poly-silicon mask layers 114 on top of the trenches 104 with the gate recess opening 116 is shown in FIG. 11.

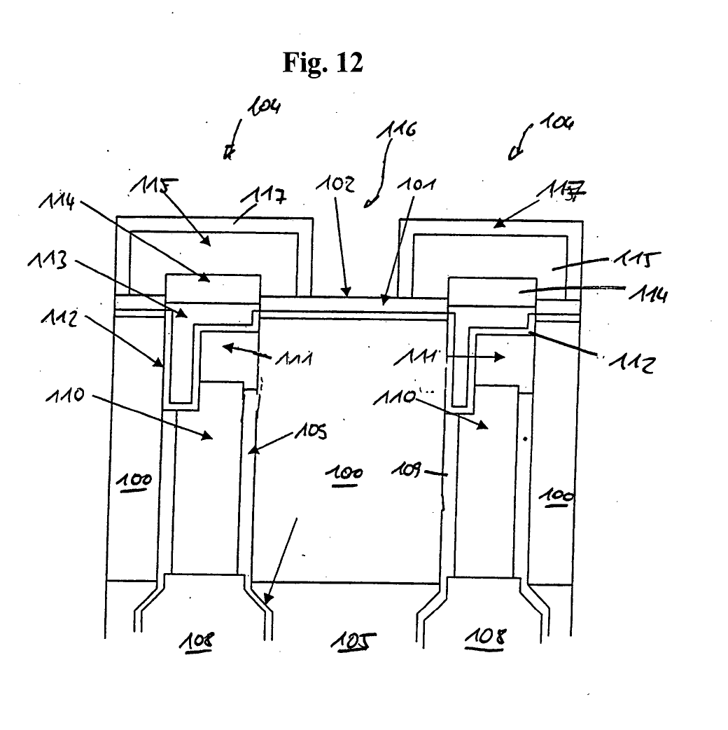

Optionally, it is possible to increase the distance between the trench capacitor and the gate electrode recess of the selection transistor by oxidizing the poly-silicon mask layers 115 to form a further oxide layer 117 as shown in FIG. 12.

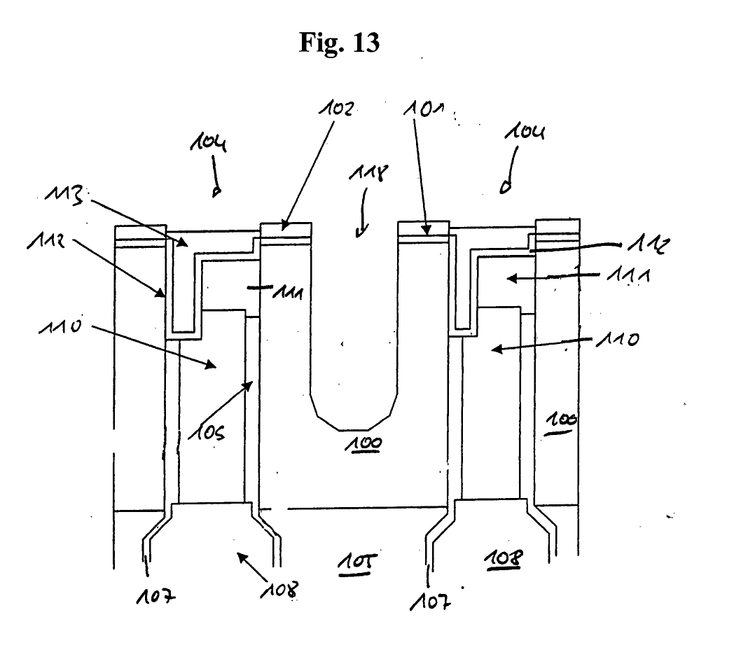

As a next process step, the pad nitride layer 102 and the pad oxide 101 are anisotropically etched by means of the poly-silicon mask 115 on top of the trenches 104. Subsequently, the gate electrode recess 118 is etched into the silicon substrate 100. Then, the poly-silicon mask 115 and the poly-silicon cap 114 on top of the trenches 104 are removed. This state of the method is shown in FIG. 13.

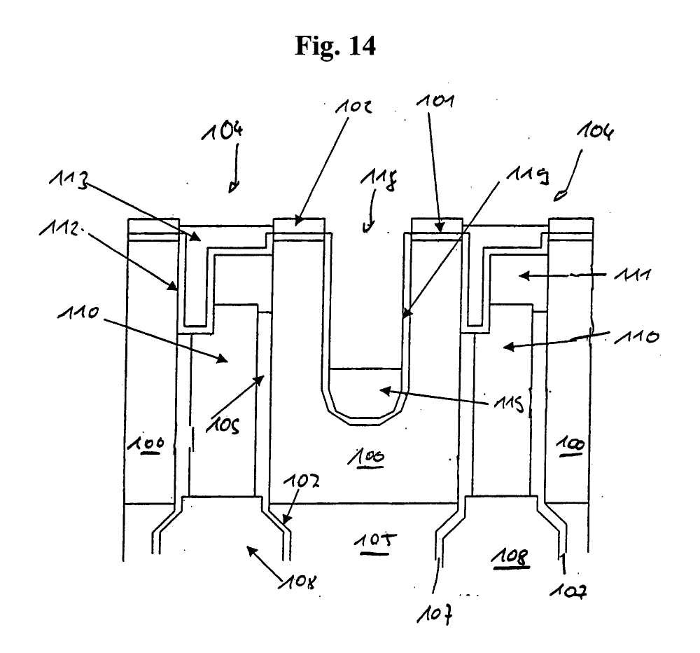

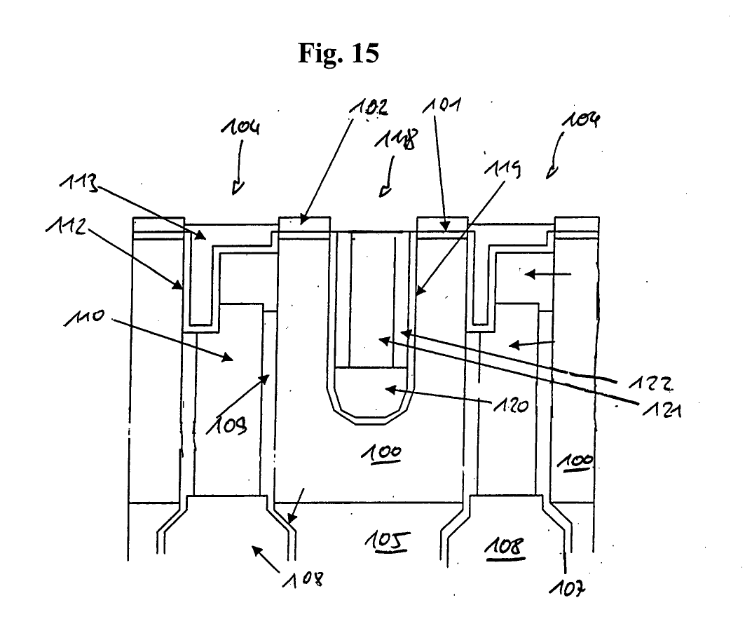

As a next step, an optional short oxide etching is carried out in order to produce a selection transistor with corner devices. Then, the gate electrode is formed. First, a gate oxide 119 is applied to the sidewalls of the recess 118 formed by a thermal process. In the following step, the recess 118 is filled by a n-doped poly-silicon 120. This poly-silicon filling 120 is etched back into the recess to a predetermined depth approximately 100 nm underneath the surface. This method step is illustrated in FIG. 14. Then, a oxide layer 121 is deposited in the recess 118 on top of the poly-silicon filling 120, the oxide being anisotropically etched so that the oxide remains on the sidewalls of the recess 119. Subsequently, the recess 118 is filled with n-doped poly-silicon 122 which is etched back down to the upper edge of the pad oxide layer 101. This state of the method is shown in FIG. 15.

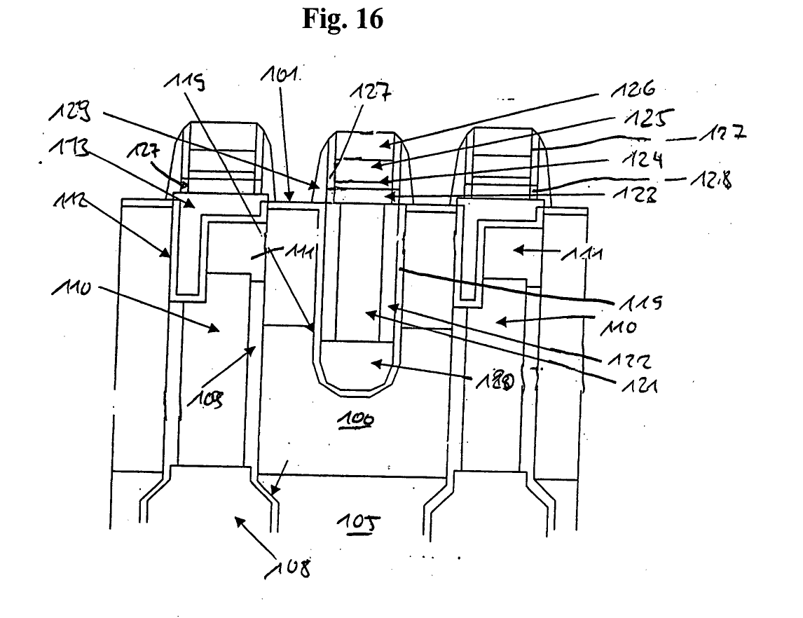

In the following process sequence, the source/drain areas of the selection transistors are carried out. In a first step, the pad nitride layer 102 is removed. Then the source/drain areas of the selection transistors are carried out by doping through the exposed pad oxide layer 101 into silicon substrate 100. Subsequently, the word lines of the memory device are formed according to a checkerboard pattern. After a short wet chemical over-etch to remove oxide remainders from the surface, a thin n-doped poly-silicon layer 123, a barrier layer 124, preferably a tungsten nitride layer, a metal layer 125, preferably a tungsten layer, and a nitride layer 126 as a cap layer are deposited. By means of a lithographic process the layer system is structured to design the word lines. The width of word lines can be relatively narrow since the line width does not determine the gate length, as is the case in the prior art. After structuring, the word lines are enclosed by a nitride layer 127 to avoid an oxidation of the metal layer 125 by the subsequent sidewall 128 oxidation step. Then, sidewall spacers 129 preferably made of oxide or nitride are formed between the word lines. The state of the method is illustrated in FIG. 16.

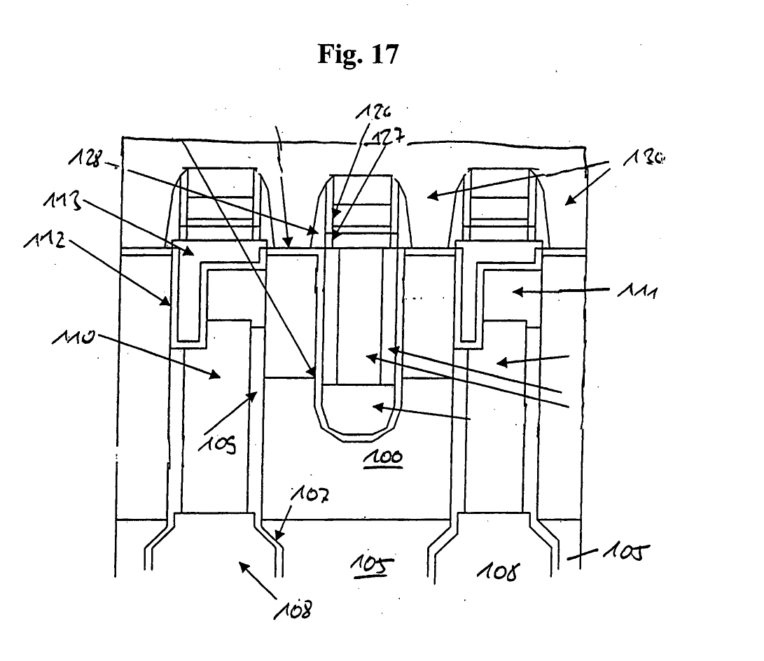

As a next step, an insulating layer 130, preferably of a glass-like material such as BPSG is deposited. After the re-flow of the BPSG layer, the BPSG is polished back as shown in FIG. 17. Optionally, a further thin oxide layer is grown by means of CVD technique.

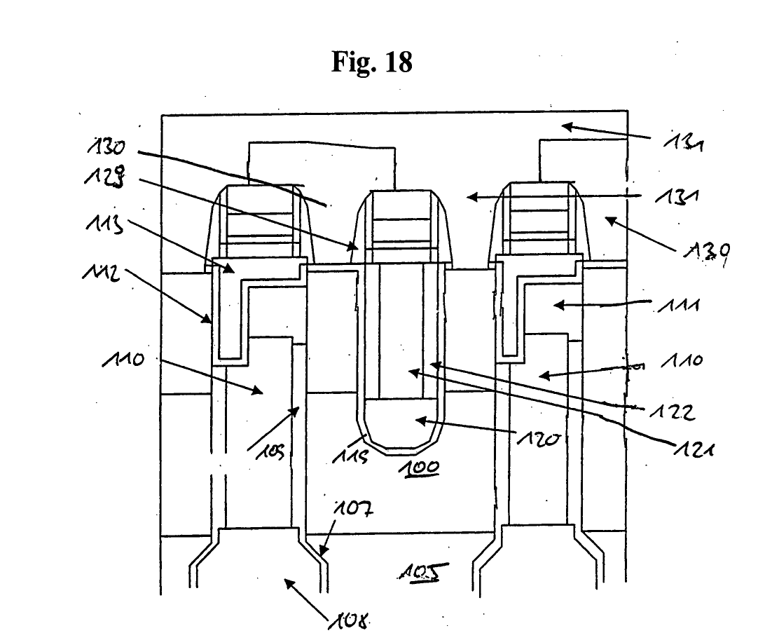

As a last process step, the bit lines 130 with the bit line contacts are formed. The formation of bit lines 130 with the bit contacts, the filling of the bit lines and the bit line contacts with metal are shown in FIG. 18.

The preceding description only describes advantageous exemplary embodiments of the invention. The features disclosed herein and in the claims and the drawings can therefore be essentially used both individually and in any desired combination for implementing the invention in its various embodiments.

What is claimed is:

1. A semiconductor memory including an array of memory cells, each memory cell comprising:
a trench capacitor, the trench capacitor including an inner electrode, an outer electrode and a dielectric layer disposed between the inner electrode and the outer electrode; and
a selection transistor, the selection transistor comprising a first source/drain area, a second source/drain area and a channel region disposed between the first source/drain area and the second source/drain area in a recess, wherein
the trench capacitor and the selection transistor of each memory cell being disposed side by side, the first source/drain area of the selection transistor being electrically connected to the inner electrode of the trench capacitor, and
the recess in which the channel region of the selection transistor is formed being located self-aligned between the trench capacitor of the memory cell and the trench capacitor of an adjacent memory cell.

2. The semiconductor memory of claim 1, wherein the spacing between the gate recess of the selection transistor and the trench capacitor of the memory cell substantially corresponds to the spacing between the gate recess of the selection transistor and the trench capacitor of the adjacent memory cell.

3. The semiconductor memory of claim 1, wherein the memory cells are arranged in rows and columns, wherein the trench capacitor and the selection transistor of each memory cell are arranged along the bit lines allocated to the rows and are arranged orthogonal to the word lines allocated to the columns.

3. The semiconductor memory of claim 1, wherein the first source/drain area of the selection transistor is electrically connected via a buried strap area with the inner electrode of the trench capacitor.

4. A method for forming a semiconductor memory on a semiconductor substrate, comprising:
forming an array of trench capacitors with the semiconductor substrate, each trench capacitor including an inner electrode, an outer electrode and a dielectric layer disposed between the inner electrode and the outer electrode; and
forming an array of selection transistors, each selection transistor comprising a first source/drain area, a second source/drain area and a channel region disposed between the first source/drain area and the second first source/drain area in a recess, wherein
the trench capacitor and the selection transistor of each memory cell is disposed side by side, the first source/drain area of the selection transistor being electrically connected to the inner electrode of the trench capacitor, and
the recess in which the channel region of the selection transistor is formed is located self-aligned between the trench capacitor of the memory cell and the trench capacitor of an adjacent memory cell.

5. The method of claim 4, wherein forming an array of trench capacitors comprises:
etching of an array of trenches into the semiconductor substrate;
doping the semiconductor substrate around the lower part of the trenches to form the outer electrodes,
disposing a dielectric layer on the wall of the trenches;
filling the trenches with a first conductive material to form the inner electrodes;
etching the first inner electrode filling back to a first depth of the trenches;
coating the exposed wall of the trenches above the inner electrode with a first insulation layer;
filling the trenches with a second conductive material to form an electrical connection to the inner electrode;
etching the second conductive material back to a second depth of the trenches being lesser than the first depth;
removing the first insulation layer coating from the wall of the trenches;
filling the trenches with a third conductive material, etching the third conductive material in a manner to form a buried strap at a wall region of the trenches;
filling the trenches with a second insulation material; and
forming a step between the second insulation material and the adjacent regions such that the second insulation material protrudes, and
wherein forming an array of selection transistors in comprises:
selectively growing on the second insulation material a spacer, the thickness of the spacer substantially corresponding to the spacing between the channel region of the selection transistor and the trench;
etching an array of recesses into the semiconductor substrate using the spacer as a mask;
disposing a gate insulation layer on the wall of the recesses;
filling the recesses with a fourth conductive material to form the gate electrodes;
etching the fourth conductive material back to a third depth of the recesses;
coating the exposed wall of the recesses above the fourth conductive material with a third insulation layer,
filling the recesses with a second conductive material to form an electrical connection to the gate electrodes, etching the spacer; and
doping the semiconductor substrate on both sides of the recesses down to the third depth of the recesses to form the first source/drain area and the second source/drain area, the first source/drain area adjoining the buried strap at the wall region of the trenches.

6. The method of claim 5, wherein a pad layer is formed on the regions adjacent to the second insulation material filling the trenches, and the step between the second insulation material and the adjacent regions is formed by etching the pad layer anisotropic and selectively to the second insulation material.

7. The method of claim 5, wherein the second insulation material on top of the trenches is a multiple layer system having a poly-silicon layer on top, and
a spacer selectively growing on the second insulation material is a poly-silicon spacer.

8. The method of claim 6, wherein the poly-silicon spacer is oxidized after deposition.

9. The method of claim 5, wherein a pad multi layer system serves as an etching mask for etching the trenches, the multi layer system includes a basis layer an silicon oxide layer.

10. The method of claim 5, wherein the doping of the third conductive material forming the buried strap at a wall region of the trenches is selected such that the temperature budget of the succeeding processes is taken into account in a sufficient quantity of dopant out-diffuses to ensure a sufficiently low impedance connection of the inner electrode of the trench capacitors to the second source/drain area of the selection transistors.

11. The method of claim 5, wherein the etching of the third conductive material in a manner to form the buried strap at a wall region of the trenches includes locally changing the etching rate of a sacrificial layer on top of the third conductive material by a tilted implantation, and
removing the region of the third conductive material beneath the sacrificial layer showing the tilted implantation.

12. The method of claim 5, wherein filling of the trenches with the second insulation material includes growing a thin silicon dioxide layer, filling the trenches with a CVD oxide, and back-polishing the CVD oxide.

13. The method of claim 5, wherein after filling of the trenches with the second insulation material shallow trench isolations between adjacent memory cells are performed.
